(19) United States
(12) Patent Application Publication
(10) Pub. No.: US 2025/0072086 A1
(43) Pub. Date: Feb. 27, 2025

(54) MICROELECTRONIC COMPONENT AND METHOD FOR PRODUCING A MICROELECTRONIC COMPONENT

(71) Applicant: Robert Bosch GmbH, Stuttgart (DE)

(72) Inventors: Franz Dietz, Willmandingen (DE); Wolfgang Feiler, Reutlingen (DE)

(21) Appl. No.: 18/805,866

(22) Filed: Aug. 15, 2024

(30) Foreign Application Priority Data
Aug. 22, 2023 (DE) 10 2023 207 992.5

(51) Int. Cl. H01L 29/40; H01L 21/765

(52) U.S. Cl. CPC H01L 29/408; H01L 21/765

(57) ABSTRACT

A microelectronic component. The microelectronic component includes a metallic conductor on a first dielectric layer, wherein the metallic conductor has a polygonal, in particular rectangular, cross-section, and the metallic conductor has a region with a corner, wherein the corner faces away from the first dielectric layer. At least one second layer with a second permittivity and a second conductivity is arranged on the region with the corner, and a fourth layer with a fourth permittivity and a fourth conductivity is arranged on the second layer, The second permittivity has a higher value than the fourth permittivity and the second conductivity has a higher value than the fourth conductivity.

### FIELD

The present invention relates to a microelectronic component and to a method for producing a microelectronic component.

### BACKGROUND INFORMATION

Galvanic isolation is used in the data transmission between different voltage domains in the high-voltage range. The data transmission itself can take place optically and, in the case of integrated galvanic isolation, inductively or capacitively. In the automotive sector, the coils of the inductance or the plates of the capacitors are sometimes at very different electrical potentials. The difference in potentials is in the range above 500 V.

The galvanic isolation is integrated either directly into the semiconductor technology of the ASIC or as a separate chip in a system-in-package. The maximum load capacity and service life of the isolation are defined by the maximum electric field within the isolation structure.

A disadvantage here is that weak points arise at the corners and edges of the conductive materials due to field enhancements.

U.S. Pat. No. 9,299,697 B2 describes galvanic isolation by means of a capacitor, in which an isolating layer is arranged below the upper plate of the capacitor.

A disadvantage here is that a slow-onset degradation effect above the metallic plate affects the service life of the component.

German Patent Application No. DE 10 2013 206 899 A1 describes the rounding of corners and edges.

A disadvantage here is that only thick metal layers can be processed.

An object of the present invention is to overcome these disadvantages.

### SUMMARY

According to an example embodiment of the present invention, a microelectronic component includes a metallic conductor on a first dielectric layer, wherein the metallic conductor has a polygonal, in particular rectangular, cross-section, and the metallic conductor has a region with a corner, wherein the corner faces away from the first electrical layer. According to the present invention, at least one second layer with a second permittivity and a second conductivity is arranged on the region with the corner. A fourth layer with a fourth permittivity and a fourth conductivity is arranged on the second layer, wherein the second permittivity has a higher value than the fourth permittivity and the second conductivity has a higher value than the fourth conductivity. In other words, a metal edge or corner is surrounded by a field-reducing multi-layer system.

An advantage here is that the electric field at the metal edge is low, so that the service life of the component is increased.

In a development of the present invention, the corner is rounded.

An advantage here is that the electric field at the metal edge is further reduced.

In a further embodiment of the present invention, the metallic conductor is arranged within a high-voltage region and the corner faces a low-voltage region.

An advantage here is that the dielectric strength in the high-voltage region of the component is increased. Furthermore, the service life of the component for high voltages is significantly improved.

In a development of the present invention, a third layer with a third permittivity and a third conductivity is arranged in regions on the at least one second layer, wherein the third permittivity has a value between the second permittivity and the fourth permittivity and the third conductivity has a value between the second conductivity and the fourth conductivity.

An advantage here is that electric fields, in particular at curves, corners and edges of the at least one second layer, are reduced, whereby the reliability of the component is increased.

In a further example embodiment of the present invention, the third layer is arranged in regions on a sixth dielectric layer, wherein the sixth dielectric layer is arranged between the metallic conductor and the first dielectric layer.

An advantage here is that electric fields, in particular at curves, corners and edges of the at least one second layer, are reduced. Furthermore, field-increasing corners in the third layer are avoided and the reliability of the component is further increased.

In a development of the present invention, the at least one second layer has defects.

An advantage here is that a Poole-Frenkel conduction mechanism is used, which drastically reduces the electric field at the edge.

In a further embodiment of the present invention, the dielectric layer comprises SiN.

An advantage here is that charges introduced as a result of high voltage loads and the associated field loads can flow away. Furthermore, SiN is a material widely used in semiconductor process control.

In a further example embodiment of the present invention, the metallic conductor is part of a capacitor.

In a further example embodiment of the present invention, the metallic conductor is part of a coil.

A method according to an example embodiment of the present invention for producing a microelectronic component comprising a metallic conductor on a first dielectric layer, wherein the metallic conductor has a polygonal, in particular rectangular, cross-section, and the metallic conductor has a region with a corner, wherein the corner faces away from the first dielectric layer, comprises applying a second layer with a second permittivity and a second conductivity to the region with the corner by means of CVD, PE-CVD, HDP-CVD, ALD, or electroless galvanic deposition, and applying a fourth layer with a fourth permittivity and a fourth conductivity by means of CVD, PE-CVD, HDP-CVD, ALD, or electroless galvanic deposition, wherein the second permittivity has a higher value than the fourth permittivity and the second conductivity has a higher value than the fourth conductivity.

An advantage here is that the production of the multi-layer system is simple.

Further advantages can be found in the following description of exemplary embodiments and in the disclosure herein.

### BRIEF DESCRIPTION OF THE DRAWINGS

The present invention is explained below with reference to preferred embodiments and the figures.

FIG. 1A shows a microelectronic component according to an example embodiment of the present invention.

FIG. 1B shows a detail of a first exemplary embodiment of the microelectronic component according to the present invention.

FIG. 2 shows a detail of a second exemplary embodiment of the microelectronic component, according to the present invention.

FIG. 3 shows a detail of a third exemplary embodiment of the microelectronic component, according to the present invention.

### DETAILED DESCRIPTION OF EXAMPLE EMBODIMENTS

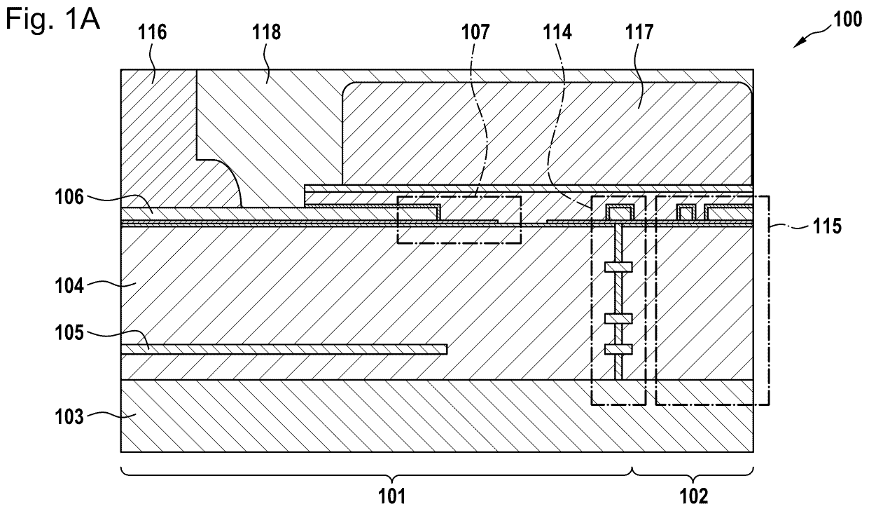

FIG. 1A shows a microelectronic component 100 according to the present invention. The microelectronic component 100 has a high-voltage region 101 and a low-voltage region 102. The microelectronic component 100 comprises a semiconductor substrate 103, for example made of silicon. Alternatively, the semiconductor substrate 103 may comprise wide-bandgap materials, such as SiC or GaN. A first dielectric layer 104 is arranged on the semiconductor substrate 103, which is, for example, at reference potential, i.e., ground. In the high-voltage region 101, a capacitor for galvanic isolation is shown by way of example. Alternatively, a coil, not shown here, may however also be provided. A first metallic plate 105 is therefore arranged within the first dielectric layer. A metallic conductor 106 with a rectangular cross-section is arranged at a vertical distance from the first metallic plate 105. The metallic conductor 106 has a region 107 with a corner or edge of the metallic conductor 106. The corner or edge faces away from the first dielectric layer 104 and faces the low-voltage region 102 or a ground terminal 114. The low-voltage region 102 comprises various components 115. In this exemplary embodiment, the metallic conductor 106 is electrically connected by means of a high-voltage terminal 116. Above the region 107, polyimide 117 is arranged in regions. The polyimide 117 is mechanically separated from the high-voltage terminal 116 by a molding compound 118.

FIG. 1B shows a detail of a first exemplary embodiment of the microelectronic component 100. The detail shows the region 107 of FIG. 1A. A sixth dielectric layer 110 is arranged on the first dielectric layer 104. A fifth dielectric layer 108 is arranged on the sixth dielectric layer 110. A metallic conductor 106 with a rectangular cross-section is arranged in regions on the fifth dielectric layer 108. The metallic conductor comprises a corner or edge facing away from the first dielectric layer 104. It is located on an upper side of the metallic conductor 106. A second layer 109 with a second permittivity and a second conductivity is arranged in regions on the metallic conductor 106. A fourth layer 111 with a fourth permittivity and a fourth conductivity is arranged on the second layer 109. The second permittivity is greater than the fourth permittivity. The second conductivity is also greater than the fourth conductivity. The second layer 109 comprises, for example, SiN and the fourth layer 111 comprises, for example, SiO2. The fourth layer 111 acts as passivation. A top passivation 112 is arranged on the fourth layer 111 and comprises, for example, SiON. The sixth dielectric layer 110 comprises, for example, SiON and the fifth dielectric layer 108 comprises, for example, SiN.

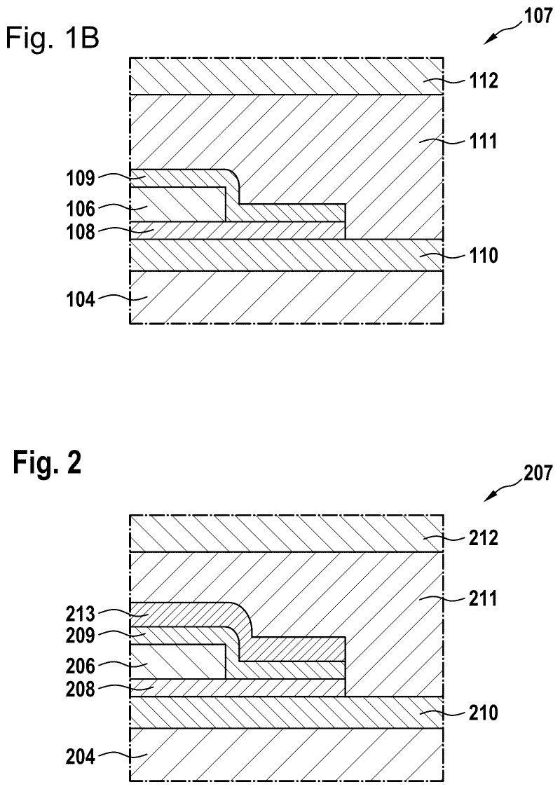

FIG. 2 shows a detail of a second exemplary embodiment of the microelectronic component. The detail shows the region 207, which can be arranged at the location of the region 107 in FIG. 1A. Identical numbers at the end of the reference signs in FIG. 2 correspond to the features of FIG. 1B. A third layer 213 is arranged between the second layer 209 and the fourth layer 211, wherein the third layer 213 ends flush with the second layer 209 in the direction of the low-voltage region. The third layer 213 has a third permittivity and a third conductivity. The value of the second permittivity is greater than the value of the third permittivity, and the value of the third permittivity is greater than the value of the fourth permittivity. The second conductivity is greater than the third conductivity, and the third conductivity is greater than the fourth conductivity.

In an alternative exemplary embodiment, the permittivity may decrease continuously from the second layer 209 to the fourth layer 211, so that no permittivity jumps occur at the layer transitions between the second layer 209, the third layer 213 and the fourth layer 211.

In both the first exemplary embodiment and the second exemplary embodiment, etching of the second layer 109 and 209 and of the third layer 213 takes place together after the structuring of the metallic layer 106 and 206.

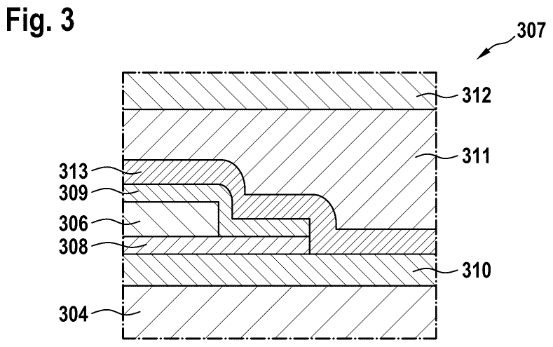

FIG. 3 shows a detail of a third exemplary embodiment of the microelectronic component. The detail shows the region 307, which can be arranged at the location of the region 107 in FIG. 1A. Identical numbers at the end of the reference signs in FIG. 3 correspond to the features of FIG. 2. The third layer 313 does not end flush with the second layer 309 since the third layer 313 is deposited on the second layer 309 after the structuring of the second layer 309. As a result, the corner or edge of the second layer 309 is also protected from high fields.

The second layer 109, 209 and 309 may, for example, be metallic. Alternatively, the second layer 109, 209 and 309 has defects, so that a Poole-Frenkel conduction mechanism can be generated during operation of the microelectronic device 100.

Alternatively, the second layer 109, 209 and 309 comprises SiN.

The third layer 213 and 313 comprises, for example, SiON.

The present invention can also be applied to metallic conductors with a rectangular or polygonal cross-section in the low-voltage region 102 or at the ground terminal 114. Furthermore, the present invention can be applied in deeper layers, for example in lower metal planes within the first dielectric layer.

The high-voltage component can comprise both a capacitor and a coil. That is to say, the applicability of the present invention is not limited to capacitive couplers but can also be used for inductive couplers or a combination of the two.

The structures according to the present invention can be used both in a chip that comprises only galvanic isolation structures, e.g., for signal transmission from the high-voltage side to the low-voltage side, or vice versa, and in a chip that additionally comprises other electrical components, such as resistors, capacitors, coils and transistors.

Furthermore, there is no restriction on the number of conductive metal layers in the chip.

Furthermore, the present invention can also be used for other conductive layers, such as polysilicon. The conductive layers can have any three-dimensional shape.

1-10. (canceled)

11. A microelectronic component, comprising:
a first dielectric layer;
a metallic conductor on the first dielectric layer, wherein the metallic conductor has a polygonal cross-section, and the metallic conductor has a region with a corner, wherein the corner faces away from the first dielectric layer;
at least one second layer with a second permittivity and a second conductivity arranged on the region with the corner; and
a fourth layer with a fourth permittivity and a fourth conductivity arranged on the second layer;
wherein the second permittivity has a higher value than the fourth permittivity and the second conductivity has a higher value than the fourth conductivity.

12. The microelectronic component according to claim 11, wherein the corner is rounded.

13. The microelectronic component according to claim 11, wherein the metallic conductor is arranged within a high-voltage region and the corner faces a low-voltage region.

14. The microelectronic component according to claim 11, further comprising:
a third layer with a third permittivity and a third conductivity arranged in regions on the at least one second layer, wherein the third permittivity has a value between the second permittivity and the fourth permittivity and the third conductivity has a value between the second conductivity and the fourth conductivity.

15. The microelectronic component according to claim 14, further comprising:
a sixth dielectric layer, wherein the third layer is arranged in regions on the sixth dielectric layer, wherein the sixth dielectric layer is arranged between the metallic conductor and the first dielectric layer.

16. The microelectronic component according to claim 11, wherein the at least one second layer has defects.

17. The microelectronic component according to claim 11, wherein the at least one second layer includes SiN.

18. The microelectronic component according to claim 11, wherein the metallic conductor is part of a capacitor.

19. The microelectronic component according to claim 11, wherein the metallic conductor is part of a coil.

20. A method for producing a microelectronic component including a metallic conductor on a first dielectric layer, wherein the metallic conductor has a polygonal cross-section, and the metallic conductor has a region with a corner, wherein the corner faces away from the first dielectric layer, the method comprising the following steps:
applying a second layer with a second permittivity and a second conductivity to the region with the corner by CVD, or PE-CVD, or HDP-CVD, or ALD, or electroless galvanic deposition; and
applying a fourth layer with a fourth permittivity and a fourth conductivity to the region with the corner by CVD, or PE-CVD, or HDP-CVD, or ALD, or electroless galvanic deposition, wherein the second permittivity has a higher value than the fourth permittivity and the second conductivity has a higher value than the fourth conductivity.
